(19) United States
(12) Patent Application Publication
(10) Pub. No.: US 2014/0146589 A1
(43) Pub. Date: May 29, 2014

(54) SEMICONDUCTOR MEMORY DEVICE WITH CACHE FUNCTION IN DRAM

(71) Applicant: SAMSUNG ELECTRONICS CO., LTD., Suwon-Si (KR)

(72) Inventors: CHULSUNG PARK, Seoul (KR); DONGSOO JUN, Seoul (KR); JOOSUN CHOI, Yongin-si (KR)

(73) Assignee: SAMSUNG ELECTRONICS CO., LTD., Suwon-Si (KR)

(21) Appl. No.: 13/832,996

(22) Filed: Mar. 15, 2013

Related U.S. Application Data
(60) Provisional application No. 61/731,088, filed on Nov. 29, 2012.

(30) Foreign Application Priority Data
Feb. 20, 2013 (KR) 10-2013-0018070

(51) Int. Cl. G11C 5/02

(52) U.S. Cl. CPC G11C 5/02
USPC 365/51

(57) ABSTRACT

A semiconductor memory device is provided which includes a dynamic random access memory including a memory cell array formed of dynamic random access memory cells; a cache memory formed at the same chip as the dynamic random access memory and configured to communicate with a processor or an external device; and a controller connected with the dynamic random access memory and the cache memory in the same chip and configured to control a dynamic random access function and a cache function.

### CROSS-REFERENCE TO RELATED APPLICATIONS

This U.S. non-provisional application claims priority under 35 U.S.C. §119 to U.S. provisional application No. 61/731,088 filed on Nov. 29, 2012 and to Korean Patent Application No. 10-2013-0018070 filed Feb. 20, 2013, in the Korean Intellectual Property Office, the disclosures of which are incorporated by reference herein in their entireties.

### BACKGROUND

The various embodiments described herein relate to a semiconductor memory device, and more particularly, relate to a semiconductor memory device with a cache function in a dynamic random access memory.

A semiconductor memory device such as a random access memory (for example, a dynamic RAM or DRAM) may be widely used as a main memory of an electronic device (e.g., mobile device or computer).

The DRAM may be controlled by a memory controller called a chipset. The chipset may include a cache memory (e.g., a static RAM or SRAM) to process data in high speed.

A capacity of the cache memory included in the chipset may be small while a capacity of the DRAM may increase. Thus, in the event that a cache memory is used for a large-capacity DRAM, the increase in a chip size may have a limited effect due to the size constraints of the cache memory.

If the chipset and the large-capacity DRAM are included in a single package, a cache memory included in the chipset may have a bad effect on scale-down of the chipset, due to the need for a larger cache memory, and therefore improvement of a fabricating yield may suffer.

### SUMMARY

One aspect of embodiments is directed to provide a semiconductor memory device which comprises a dynamic random access memory including a memory cell array formed of dynamic random access memory cells; a cache memory formed at the same chip as the dynamic random access memory and configured to communicate with a processor or an external device; and a controller connected with the dynamic random access memory and the cache memory in the same chip and configured to control a dynamic random access function and a cache function.

In one embodiment, the cache memory is configured to communicate with the processor or the external device without the need to communicate through circuitry of the dynamic random access memory.

In example embodiments, the cache memory comprises a cache memory cell array having dynamic random access memory cells each having line loading smaller than the dynamic random access memory cells of the dynamic random access memory.

In example embodiments, the cache memory comprises a cache memory cell array configured with the same layout as bit line sense amplifiers of the dynamic random access memory.

In example embodiments, the cache memory comprises a first cache cell array configured with the same layout as bit line sense amplifiers of the dynamic random access memory; and a second cache cell array formed of memory cells each having line loading smaller than the dynamic random access memory cells of the dynamic random access memory.

In example embodiments, the cache memory is electrically connected with a processor through bumps.

In example embodiments, the cache memory is electrically connected with an external device through bumps and through-substrate vias.

In example embodiments, the semiconductor memory device and the processor are stacked on a printed circuit board and provided in the form of a package.

In example embodiments, the cache memory comprises a first cache cell array configured with the same layout as bit line sense amplifiers of the dynamic random access memory; and an MRAM cache cell array formed of MRAM cells.

In example embodiments, the cache memory cell array further comprises an RRAM cache cell array formed of RRAM cells.

In example embodiments, the cache memory cell array further comprises an SRAM cache cell array formed of SRAM cells.

In certain embodiments, a semiconductor memory device includes a dynamic random access memory (DRAM) including a DRAM portion and a cache memory portion on the same chip. The DRAM portion includes circuitry sufficient to perform read and write operations on DRAM cells included in the DRAM portion in response to instructions from a controller. The cache memory portion includes circuitry for performing caching functions in response to instructions from the controller, a processor, or an external device.

In one embodiment, the cache memory portion comprises a cache memory cell array having dynamic random access memory cells each having line loading smaller than dynamic random access memory cells of the DRAM portion.

The cache memory portion may be configured to perform faster read and write operations than the DRAM portion.

The cache memory portion may be configured to communicate with a processor or an external device without the need to communicate through circuitry of the DRAM portion.

The cache memory portion may further be configured to communicate with a controller, processor, or external device through a first set of conductive terminals, and the DRAM portion is configured to communicate with a controller through a second set of conductive terminals that are separate from the first set of conductive terminals.

In one embodiment, the semiconductor memory device is configured to communicate with a processor, and the semiconductor memory device and the processor are stacked on a printed circuit board and provided in the form of a package.

In certain embodiments, a semiconductor memory device includes a dynamic random access memory (DRAM) portion including a first memory cell array formed of DRAM cells; and a cache memory portion formed at the same chip as the DRAM portion and including a second memory cell array formed of DRAM cells. The cache memory portion is configured to perform faster read and write operations than the DRAM portion.

In one embodiment, the semiconductor memory device further includes a controller connected with the DRAM portion and the cache memory portion in the same chip and configured to control a dynamic random access function and a cache function.

The cache memory portion may be configured to communicate with a processor or an external device without the need to communicate through circuitry of the DRAM portion.

In one embodiment, the cache memory portion comprises a cache memory cell array having DRAM cells each having line loading smaller than the DRAM cells of the DRAM portion.

The cache memory portion may be configured to communicate with a controller, processor, or external device through a first set of conductive terminals, and the DRAM portion may be configured to communicate with a controller through a second set of conductive terminals that are separate from the first set of conductive terminals.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a block diagram schematically illustrating an exemplary memory system according to one embodiment.

FIG. 2 is a block diagram schematically illustrating an exemplary structure of a memory cell array of a semiconductor memory device of FIG. 1 according to one embodiment;

FIG. 3 is a block diagram schematically illustrating an exemplary structure of a memory cell array of a semiconductor memory device of FIG. 1 according to another embodiment;

FIG. 4 is a diagram illustrating a single package of a semiconductor memory device and a memory controller of FIG. 1, according to one exemplary embodiment;

FIG. 5 is a flow chart illustrating an operation of a semiconductor memory device of FIG. 1, according to one exemplary embodiment;

FIG. 6 is a block diagram schematically illustrating an exemplary semiconductor memory device according to another embodiment;

FIG. 7 is a block diagram schematically illustrating an exemplary memory system according to another embodiment;

FIG. 8 is a block diagram schematically illustrating an exemplary data storage device according to an embodiment;

FIG. 9 is a block diagram schematically illustrating an exemplary memory system according to still another embodiment;

FIG. 10 is a block diagram schematically illustrating an exemplary mobile device according to an embodiment;

FIG. 11 is a block diagram schematically illustrating an exemplary memory system according to still another embodiment;

FIG. 12 is a diagram schematically illustrating an exemplary application to which through-silicon via (TSV) is applied, according to one embodiment.

### DETAILED DESCRIPTION

Embodiments will be described in detail with reference to the accompanying drawings. The inventive concept, however, may be embodied in various different forms, and should not be construed as being limited only to the illustrated embodiments. Accordingly, known processes, elements, and techniques are not described with respect to some of the embodiments of the inventive concept. Unless otherwise noted, like reference numerals denote like elements throughout the attached drawings and written description, and thus descriptions will not be repeated. In the drawings, the sizes and relative sizes of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. Unless indicated otherwise, these terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

Embodiments disclosed therein may include their complementary embodiments. Note that details of data access operations and a refresh operation associated with a semiconductor memory device such as a DRAM may be skipped to prevent the inventive concept from becoming ambiguous.

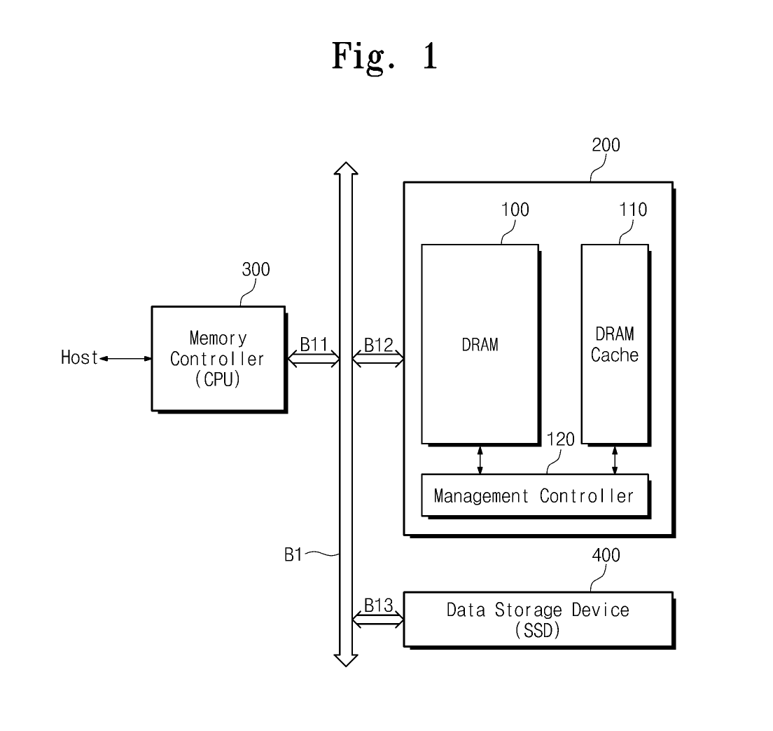

FIG. 1 is a block diagram schematically illustrating a memory system according to one embodiment.

Referring to FIG. 1, a memory system may include a semiconductor memory device 200 and a memory controller 300.

The semiconductor memory device 200 may include a DRAM 100, a DRAM cache 110, and a management controller 120.

The DRAM 100 may include a memory cell array formed of dynamic random access memory cells.

The DRAM cache 110 may function as a cache memory, and may be formed at the same chip as the DRAM 100. For example, in one embodiment, both the DRAM cache 110 and the DRAM 100 may be formed on a single layer die formed from a wafer. In one embodiment, the DRAM cache 110 and the DRAM 100 are formed together as part of the same process.

In one embodiment, the DRAM 100 shown in FIG. 1 refers to a complete functional DRAM circuit, including, for example, a memory cell array, row and column decoders, sense amplifiers, and other circuitry sufficient to allow the DRAM to function properly. In this embodiment, DRAM cache 110 refers to a separate circuit. The separate circuit may communicate with the management controller separately and independently from the DRAM 100, and in one embodiment, is not directly used by the DRAM circuitry in reading or writing to cells of the DRAM memory cell array. As such, the DRAM cache 110 may communicate with the memory controller 300, a processor, or an external device independently from the DRAM 100.

For example, in one embodiment, the DRAM cache 110 can communicate with the memory controller 300, a processor, or an external device through a first set of conductive terminals dedicated to the DRAM cache 110, without a need to communicate through conductive terminals that transfer signals to and from the DRAM cells and peripheral circuitry of the DRAM 100. Alternatively, or additionally, in one embodiment, DRAM cache 110 may connect through circuitry of the management controller 120 that is isolated from and separate from circuitry of the management controller 120 that services the DRAM 100. Alternatively, or additionally, DRAM cache 110 and DRAM 100 can communicate through separate lines of bus B1 (or can have separate buses, not shown), in order to communicate with the memory controller 300, a processor, or an external device. In any of these embodiments, the DRAM cache may be configured so that in order for an external device, a memory controller 300, or a processor to communicate with the DRAM cache 110, it does not need to send signals through the memory cells or peripheral circuitry of the DRAM 100.

The management controller 120 may be connected with the DRAM 100 and the DRAM cache 110 in the same chip to control a DRAM function and a cache function. In one embodiment, to differentiate DRAM 100 from DRAM cache 110, the DRAM 100 is referred to a DRAM portion of a memory, and the DRAM cache 110 is referred to as a cache portion of a memory. The DRAM portion may include circuitry sufficient to perform standard DRAM functions, and the cache portion may include circuitry for performing caching functions that are typically performed by a cache located at a controller for a DRAM or other memory.

The memory controller 300 may function as a chipset, and may be connected with a host. Furthermore, although memory controller 300 and management controller 120 are depicted as separate controllers in FIG. 1 and may be located at different locations or chips within a memory system, the memory controller 300 and management controller 120 may function together, and thus may be considered to be part of a controller that controls the memory system shown in FIG. 1.

A bus B11 of the memory controller 300 may be connected to a bus B1, and the bus B1 may be connected to a bus B12 of the semiconductor memory device 200.

The bus B1 may be connected with a data storage device 400, which functions as a mass storage device, through a bus B13.

In one embodiment, the DRAM cache 110 includes a cache memory cell array that has DRAM cells having word line loading or bit line loading smaller than DRAM cells of the DRAM 100. For example, in one embodiment, word lines or bit lines for the DRAM cache 110 cell array are shorter and/or thicker than word lines or bit lines for the DRAM cells of the DRAM 100. In another embodiment, as described further below, the structure of the circuit elements and cells that form the DRAM cache 110 may result in a smaller bit line or word line loading for the DRAM cache 110 cells than for the DRAM 100 cells. For example, compared with a DRAM cell having relatively large bit line loading, a DRAM cell having relatively small bit line loading may perform a read operation or a write operation more rapidly. Thus, although the DRAM cell having relatively small bit line loading may require a refresh operation more frequently, it has a function of a cache memory, including a fast operation. For example, in one embodiment, the operating speed of cells in the DRAM cache 110 may be at least twice as fast on average as the operating speed of cells in the DRAM 100. Additional examples of circuitry and other features relating to faster and slower array areas are described in Korean Patent Application No. 10-2012-0077969, filed Jul. 17, 2012, which is incorporated herein in its entirety.

The DRAM cache 110 may include a cache memory cell array that is configured the same as bit line sense amplifiers of the DRAM 100 (e.g., to have the same circuit layout, same circuit elements, same sizes, and/or same shapes, etc.). Since the bit line sense amplifier may include a latch formed of MOS transistors, it may perform substantially the same role as an SRAM cell. Thus, at a fabricating level of the DRAM, spare bit line sense amplifiers may be fabricated by a specified number to be used for a cache memory cell array.

In certain embodiments, the DRAM cache 110 may include a cache memory cell array that has a first cache cell array and a second cache cell array. The first cache cell array may be configured the same as bit line sense amplifiers of the DRAM, and the second cache cell array may be configured to include memory cells having line loading smaller than the DRAM cells.

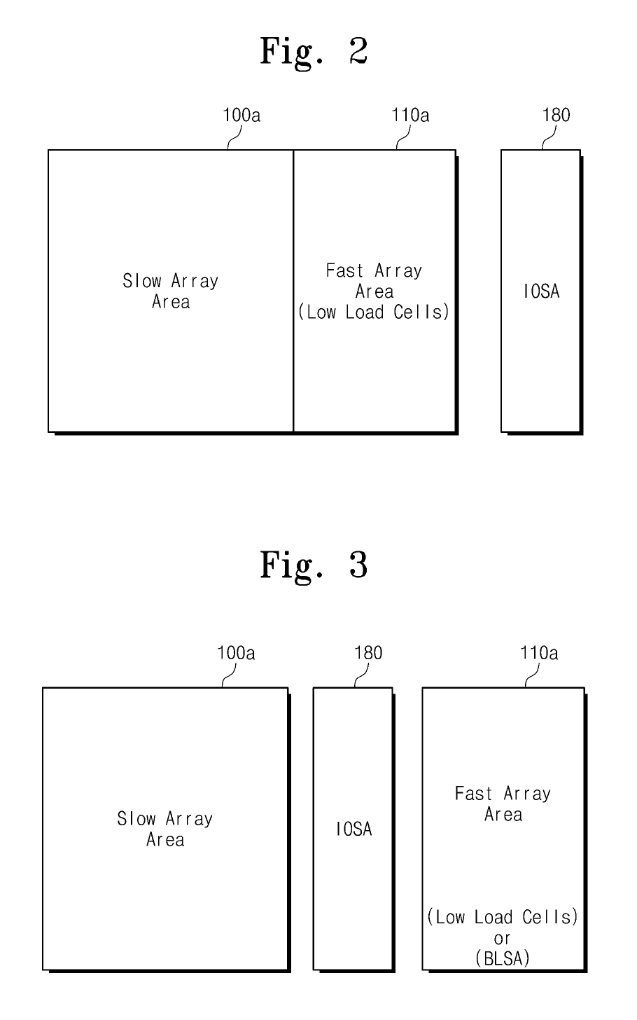

FIG. 2 is a block diagram schematically illustrating an exemplary structure of a memory cell array of a semiconductor memory device of FIG. 1 according to one embodiment.

Referring to FIG. 2, there are illustrated a memory cell array 100a as a data storage area of a DRAM 100 and a cache memory cell array 110a as a data storage area of a DRAM cache 110.

The memory cell array 100a may include a plurality of memory cells arranged in a matrix form of rows and columns. Each memory cell may be formed, for example, of an access transistor AT and a storage capacitor SC. In each memory cell, a gate of the access transistor AT may be connected with a corresponding word line WLi, and a drain thereof may be connected with a corresponding bit line BLi. A plurality of memory cells connected with the same word line may constitute a memory page.

Cache memory cells in the cache memory cell array 110a may include DRAM cells having relatively small line loading. For example, if line loading decreases according to a decrease in the number of memory cells connected with a word line or a bit line (e.g., by using shorter word lines or bit lines), a data read operation or a data write operation may be performed more rapidly. The cache memory cell array 110a may include small load cells.

Since an operating speed of the memory cell array 100a may be slower than that of the cache memory cell array 110a, the memory cell array 100a may be labeled as a slow array area. Since an operating speed of the cache memory cell array 110a may be faster than that of the memory cell array 100a, the cache memory cell array 110a may be labeled as a fast array area.

An input/output sense amplifier 180 may be disposed to be adjacent to the cache memory cell array 110a such that a time taken to input and output data to and from the cache memory cell array 110a is reduced. Thus, a high-speed cache operation may be realized.

In the cache memory cell array 110a, data stored at cache memory cells may be lost at power-off. Also, after data stored at cache memory cells is read, the read data may be lost from the cache memory cells due to a leakage current flowing at a memory operation. As such, the cache memory cell array 110a may need a refresh operation.

A refresh operation of a DRAM may be similar to a data read operation, but may be distinguished from the data read operation in that read data is not output to an external device.

In general, the refresh operation of the DRAM may be accomplished by applying an RASB (Row Address Strobe) signal having a high-to-low transition to the DRAM, activating a word line corresponding to a row address to be refreshed, and driving a bit line sense amplifier for sensing data from memory cells.

With the refresh specification of a typical 4 Mega DRAM, a refresh operation may be performed per 16 ms/1024 (cycle). As such, a refresh operation for a single row may be performed in a period of 15.6 microseconds. A memory controller 300 may apply a refresh command to a semiconductor memory device 200 in a period of 15.6 microseconds. A refresh time may be decided according to the number of rows and the number of refresh cycles of the DRAM. For example, in case of a refresh cycle for 4096 rows, a refresh time may be 64 milliseconds (15.6 μs×4096).

In case of a refresh operation, if a refresh enable signal goes to a high level according to a refresh control signal, word lines may be activated and bit line sensing may be performed. If the refresh enable signal goes to a low level, word lines may be inactivated and bit line discharging may be performed.

FIG. 3 is a block diagram schematically illustrating a structure of a memory cell array of a semiconductor memory device of FIG. 1 according to another exemplary embodiment.

Unlike a structure of FIG. 2, an input/output sense amplifier 180 may be disposed between a memory cell array 100a and a cache memory cell array 110a as illustrated in FIG. 3.

In this case, a high-speed operation may be performed without a delay of a data input/output speed of the memory cell array 100a.

Memory cells of the cache memory cell array 110a may be formed, for example, of DRAM cells having word line loading or bit line loading smaller than DRAM cells of the memory cell array 100a.

Also, in one embodiment, the memory cells of the cache memory cell array 110a may be configured the same as bit line sense amplifiers of a DRAM. In this case, like the case where the memory cells of the cache memory cell array 110a are formed of SRAM cells, the cache memory cell array 110a may not need a refresh operation.

In FIG. 3, in the case that the memory cell array 100a and the cache memory cell array 110a are implemented in the same chip, in one embodiment, a memory capacity of the memory cell array 100a may be at least 20 times larger than that of the cache memory cell array 110a. In terms of the economics, in one embodiment, a memory capacity of the memory cell array 100a is at least 6 times larger than that of the cache memory cell array 110a on the basis of a chip size.

In case of a DRAM mono die 8 Gb, in one embodiment, a required capacity of a cache memory may be about 8 MB due to the large-capacity and scaled-down DRAM. As such, the cache memory may take about 0.8% of a memory capacity of the DRAM. Also, in one embodiment, the cache memory may take about 3% to 4% of a chip size in comparison with the DRAM. In this case, it is efficient to form a DRAM and a cache memory at the same chip.

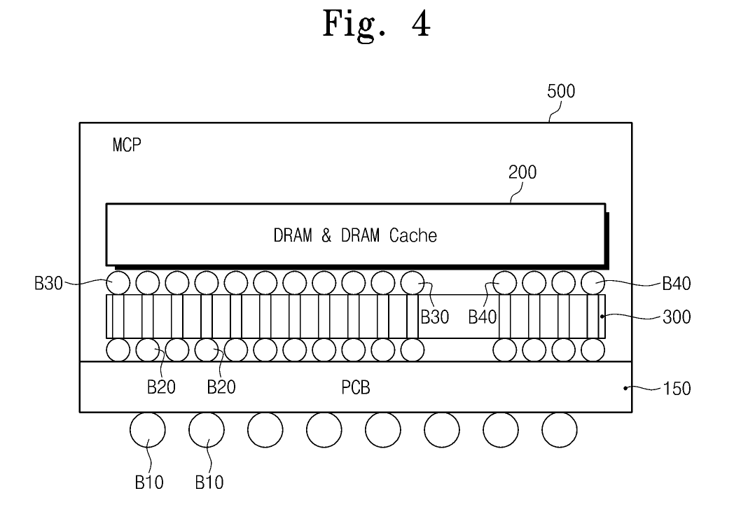

FIG. 4 is a diagram illustrating a single package of a semiconductor memory device and a memory controller of FIG. 1, according to one exemplary embodiment.

Referring to FIG. 4, a chipset 300 and a semiconductor memory device 200 may be sequentially stacked on a printed circuit board 150. A DRAM cache may be embedded in the semiconductor memory device 200.

The semiconductor memory device 200 may include a DRAM and a DRAM cache formed at the same chip. The chipset 300 may be a memory controller, which is formed, for example, at another chip.

The printed circuit board 150, the chipset 300, and the semiconductor memory device 200 including an embedded DRAM cache may be included in a multi-chip package 500.

The chipset 300 and the DRAM may be electrically connected through conductive terminals, such as micro bumps B30. The micro bumps B30 may be also called μ-Bump PAD,

Meanwhile, the chipset 300 and the DRAM 100 can be electrically connected through conductive terminals such as micro bumps B40, which are formed to be independent from the micro bumps B30. For example, micro bumps B30 and micro bumps B40 may each comprise conductive terminals for communicating outside of the semiconductor memory device 200, but may connect to separate circuitry on the semiconductor memory device 200 (e.g., DRAM and DRAM cache circuitry that is electrically isolated from each other).

Conductive terminals such as micro bumps B10 formed on a lower surface of the printed circuit board 150 may be used for electrical connection with an external device (e.g., a host).

A plurality of through substrate vias (TSVs), such as through-silicon vias may be formed in a chipset 300 such that a cache memory is electrically connected with the external device through the package substrate, which may be a printed circuit board 150. If the cache memory is controlled by the chipset 300 or the external device through a bump-to-bump connection and TSV structure, it is possible to efficiently perform the same or similar function as a case where a chipset includes a cache memory.

A cross-sectional view of FIG. 4 may be an example of a Silicon In Processor (SIP). However, the inventive concept is not limited thereto. For example, the DRAM and the DRAM cache used in a system other than depicted by the chipset 300 may be included in a package.

If a cache memory (e.g., SRAM) is removed from a chipset, an effect of lowering a yield of the cache memory at fabricating of the chipset may be removed. Also, since a chip size of the chipset may be scaled down by about 5% to 10% when removing the cache memory, it is possible to reduce a fabricating cost.

Also, in another embodiment, a cache memory function may be added in a mono chip while a cache memory embedded DRAM maintains an inherent function of the DRAM. Thus, the product competitiveness may be improved.

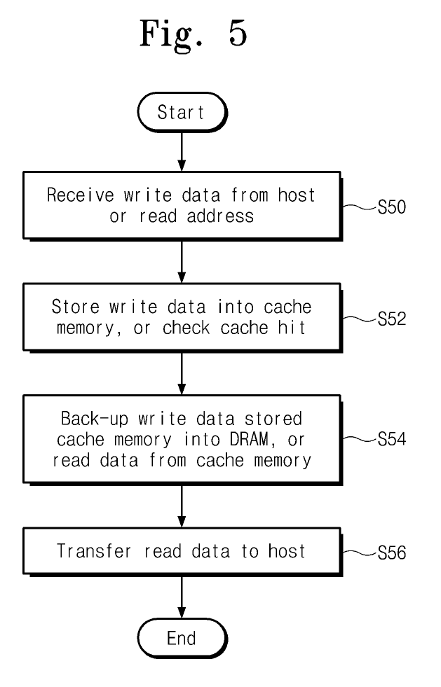

FIG. 5 is a flow chart illustrating an operation of a semiconductor memory device of FIG. 1, according to one exemplary embodiment.

Referring to FIG. 5, there is illustrated a control procedure of a management controller 120 in a semiconductor memory device 200 of FIG. 1, according to one exemplary embodiment.

In operation S50, when a write mode of operation is executed, write data may be received through a bus B1 connected with a bus B12. If a read mode of operation is executed in operation S50, a read address may be received through the bus B1 connected with the bus B12.

In operation S52, at the write mode of operation, the write data may be stored at a cache memory 110. If the read mode of operation is executed in operation S52, cache miss or cache hit may be checked using the read address.

At the write mode of operation, in operation S54, the write data stored at the cache memory 110 may be backed up to a DRAM. If the cache hit is generated at the read mode of operation, in operation S54, data may be read from the cache memory 110. If the cache miss is generated at the read mode of operation, a data storage device 400 may be accessed.

At the read mode of operation, in operation S56, read data read out from the cache memory 110 may be sent to a host. In one embodiment, if a cache hit is generated at the read mode of operation, read data read out from the cache memory 110 may be sent to a host without reading out from the DRAM 100, by control operation of the management controller 120.

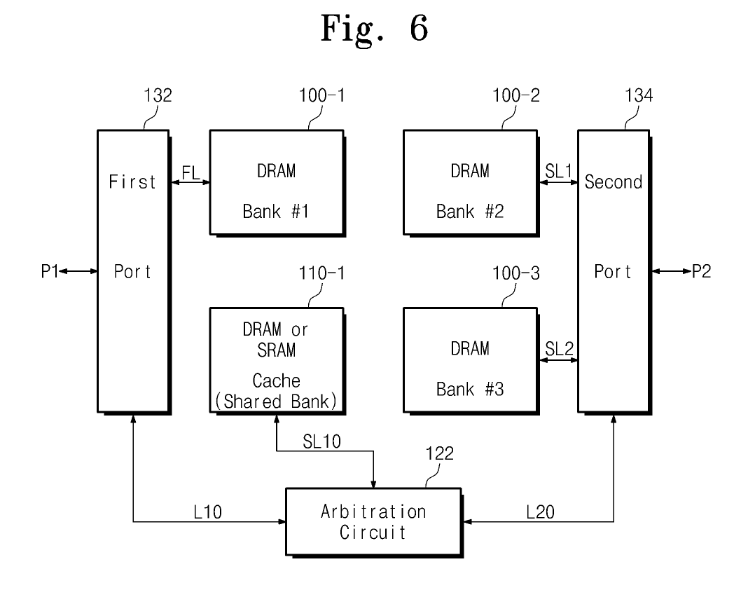

FIG. 6 is a block diagram schematically illustrating an exemplary semiconductor memory device according to another embodiment.

Referring to FIG. 6, a semiconductor memory device may include four memory banks 100-1, 100-2, 100-3, and 110-1, two ports 132 and 134, and an arbitration circuit 122.

Three memory banks 100-1, 100-2, and 100-3 of the four memory banks 100-1, 100-2, 100-3, and 110-1 may constitute a memory cell array of a DRAM. The memory cell array of the DRAM may be connected with at least two ports, and may include a plurality of memory banks each having dynamic random access memory cells.

One memory bank 110-1 of the four memory banks 100-1, 100-2, 100-3, and 110-1 may constitute a cache memory cell array of a cache memory. In one embodiment, the cache memory cell array may be formed at the same chip as the memory banks of the DRAM, and may be shared by the two or more ports at an access.

The arbitration circuit 122 may be connected to the cache memory cell array 110-1 via a line SL10 so as to be connected with one of the two or more ports 132 and 134.

The first port 132 may be connected with a first processor P1, and the second port 134 may be connected with a second processor P2. The first processor P1 may access the first memory bank 100-1 via a first line FL in a dedicated manner.

The second processor P2 may access the second and third memory banks 100-2 and 100-3 via second lines SL1 and SL2 in a dedicated manner.

The cache memory bank 110-1 may be accessed by the first and second processors P1 and P2 in a shared manner.

The semiconductor memory device of FIG. 6 may have a cache memory embedded dual access DRAM function. Thus, in the event that the semiconductor memory device is mounted at a mobile device, it may provide merits in terms of a chip size and a fabricating cost.

The cache memory bank 110-1 may be implemented by a DRAM cache or an SRAM cache as described above.

When the cache memory bank 110-1 is accessed by the first processor P1, the arbitration circuit 122 may connect lines L10 and SL10 electrically.

When the cache memory bank 110-1 is accessed by the second processor P2, the arbitration circuit 122 may connect lines L20 and SL10 electrically.

If the four memory banks 100-1, 100-2, 100-3, and 110-1 share a power line or a DC generator, the semiconductor memory device may be scaled down. Also, input/output pads, a power supply voltage, or an internal function circuit can be shared by the four memory banks 100-1, 100-2, 100-3, and 110-1.

For ease of description, components such as a row decoder, a column decoder, a read/write circuit, a refresh circuit, and so on may be skipped in FIG. 6.

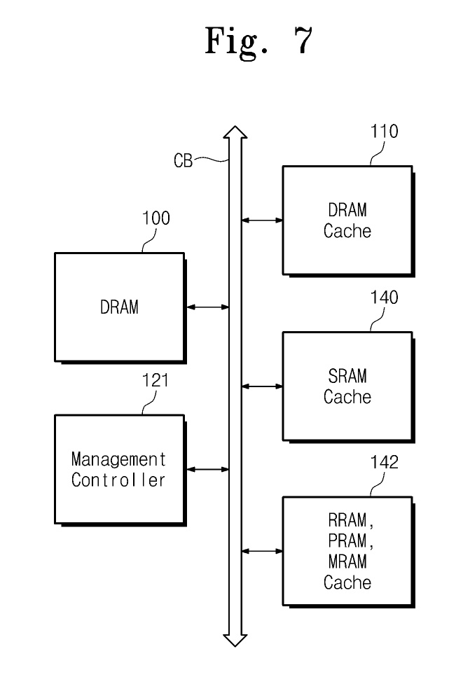

FIG. 7 is a block diagram schematically illustrating an exemplary memory system according to another embodiment.

Referring to FIG. 7, a memory system may include a DRAM 100, a DRAM cache 110, an SRAM cache 140, an RRAM cache 142, and a management controller 121.

The RRAM cache 142 can be replaced with a PRAM cache or an MRAM cache.

The DRAM 100, the DRAM cache 110, the SRAM cache 140, the RRAM cache 142, and the management controller 121 may be electrically connected through a common bus CB.

The DRAM 100 may include a memory cell array formed of dynamic random access memory cells.

The DRAM cache 110 may function as a cache memory, and may be formed at the same chip of the DRAM 100. The DRAM cache 110 may communicate with a chipset or an external device independently from the DRAM 100.

The management controller 121 may be connected with the DRAM 100, the DRAM cache 110, the SRAM cache 140, and the RRAM cache 142 in the same chip, and may control a dynamic random access function and a cache function.

In the memory system of FIG. 7, a chip of the DRAM 100 may include at least one or more caches of the DRAM cache 110, the SRAM cache 140, and the RRAM cache 142.

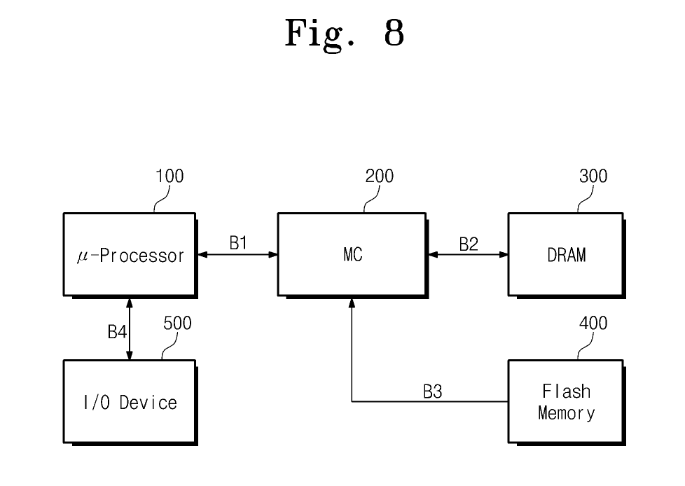

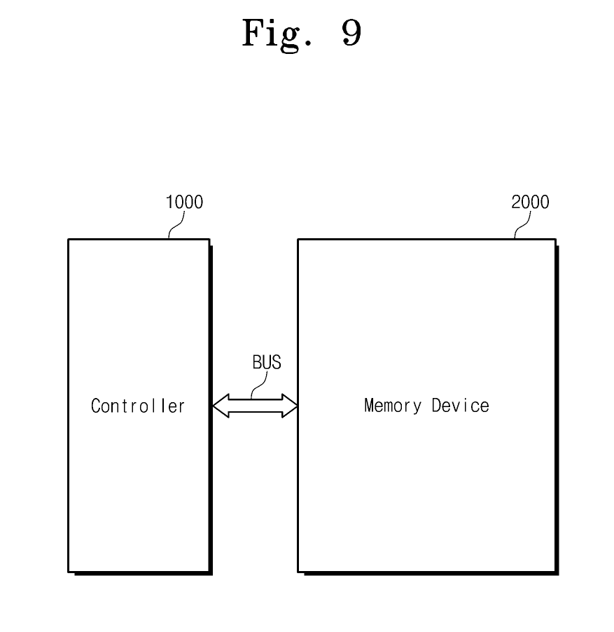

FIG. 8 is a block diagram schematically illustrating an exemplary data storage device according to one embodiment.

Referring to FIG. 8, a data storage device may include a microprocessor 100, a memory controller 200, a DRAM 300, a flash memory 400, and an input/output device 500.

The memory controller 200 connected with the microprocessor 100 via a bus B1 may be connected with the DRAM 300 via a bus B2.

As a nonvolatile memory, the flash memory 400 may be connected with the memory controller 200 via a bus B3.

The input/output device 500 may be connected with the microprocessor 100 via a bus B4.

The memory controller 200 may use the DRAM 300 as a user data buffer in the data storage device such as an SSD.

In one embodiment, the memory controller 200 does not include a cache memory, and uses a cache memory embedded in the DRAM 300 when a cache function is required.

Thus, a fabricating yield may be improved through scale-down of the memory controller functioning as a chipset. Meanwhile, since the DRAM 300 has a cache function, the product competitiveness may be bettered. Also, an independent access of an external device to the cache memory may be secured, and the memory controller 200 and the DRAM 300 may be provided in the form of a package.

FIG. 9 is a block diagram schematically illustrating an exemplary memory system according to still another embodiment.

Referring to FIG. 9, a memory system may include a controller 1000 and a memory device 2000. The controller 1000 may function as a chipset, and may not include a cache memory. The memory device 2000 may include a cache memory. The controller 1000 may send a command, an address and write data to the memory device 2000 via a bus.

Since the controller 1000 does not include a cache memory, a size of the controller 1000 may become more compact. Also, since the probability of inoperable circuitry generated when a cache memory is fabricated is lowered, a fabricating yield may be improved.

In the case that the memory device 2000 has a memory capacity of 8 Gb, an embedded cache memory may have a capacity of 8 MB. In this case, the case memory may take about 3% to 4% of a chip size of the DRAM. Thus, the operating performance of the memory system may be secured.

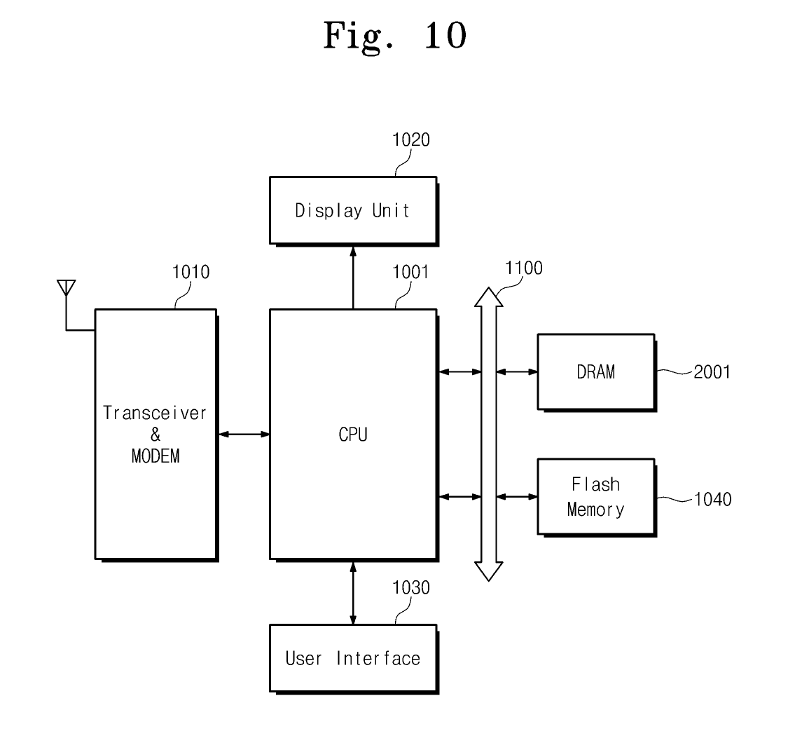

FIG. 10 is a block diagram schematically illustrating an exemplary mobile device according to one embodiment.

Referring to FIG. 10, a mobile device may include a transceiver and modem block 1010, a CPU 1001, a DRAM 2001, a flash memory 1040, a display unit 1020, and a user interface 1030.

In some cases, the CPU 1001, the DRAM 2001, and the flash memory 1040 may be provided in the form of a package or integrated to a chip. This may mean that the DRAM 2001 and the flash memory 1040 are embedded in the mobile device.

If the mobile device is a portable communications device, the transceiver and modem block 1010 may perform a communication data transmitting and receiving function and a data modulating and demodulating function.

The CPU 1001 may control an overall operation of the mobile device according to a predetermined program.

The DRAM 2001 may be connected with the CPU 1001 through a system bus 1100, and may function as a buffer memory or a main memory of the CPU 1001. The DRAM 2001 may include a cache memory, so that a cache memory is removed from the CPU 1001.

The CPU 1001 may send a command, an address, and write data to the DRAM 2001 via the system bus 1100.

Thus, a size of the CPU 1001 may be scaled down, and a fabricating yield may be improved. Meanwhile, since the DRAM 2001 has a cache function, the product competitiveness may be bettered. Also, an independent access of an external device to the cache memory may be secured, and the CPU 1001 and the DRAM 2001 may be provided in the form of a package.

The flash memory 1040 may be a NOR or NAND flash memory.

The display unit 1020 may have a liquid crystal having a backlight, a liquid crystal having an LED light source, or a touch screen (e.g., OLED). The display unit 1020 may be an output device for displaying images (e.g., characters, numbers, pictures, etc.) in color.

The user interface 1030 may be an input device including number keys, function keys, and so on, and may provide an interface between the mobile device and a user.

The disclosed embodiments may be described under assumption that the mobile device is a mobile communications device. In some cases, the mobile device may function as a smart card by adding or removing components to or from the mobile device.

In case of the mobile device, a separate interface may be connected with an external communications device. The communications device may be, for example, a DVD player, a computer, a set top box (STB), a game machine, a digital camcorder, or the like.

Although not shown in FIG. 10, the mobile device may further include an application chipset, a camera image processor (CIS), a mobile DRAM, and so on.

A DRAM (2001) chip and a CPU (1001) chip may be packed independently or using various packages. For example, a chip may be packed by a package such as PoP (Package on Package), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), System In Package (SIP), Multi Chip Package (MCP), Wafer-level Fabricated Package (WFP), Wafer-Level Processed Stack Package (WSP), or the like.

In FIG. 10, there is illustrated an example in which a flash memory is used. However, a variety of nonvolatile storages may be used.

The nonvolatile storage may store data information having various data formats such as a text, a graphic, a software code, and so on.

The nonvolatile storage may be formed, for example, of EEPROM (Electrically Erasable Programmable Read-Only Memory), flash memory, MRAM (Magnetic RAM), STT-MRAM (Spin-Transfer Torque MRAM), CBRAM (Conductive bridging RAM), FeRAM (Ferroelectric RAM), PRAM (Phase change RAM) called OUM (Ovonic Unified Memory), RRAM or ReRAM (Resistive RAM), nanotube RRAM, PoRAM (Polymer RAM), NFGM (Nano Floating Gate Memory), holographic memory, molecular electronics memory device), or insulator resistance change memory.

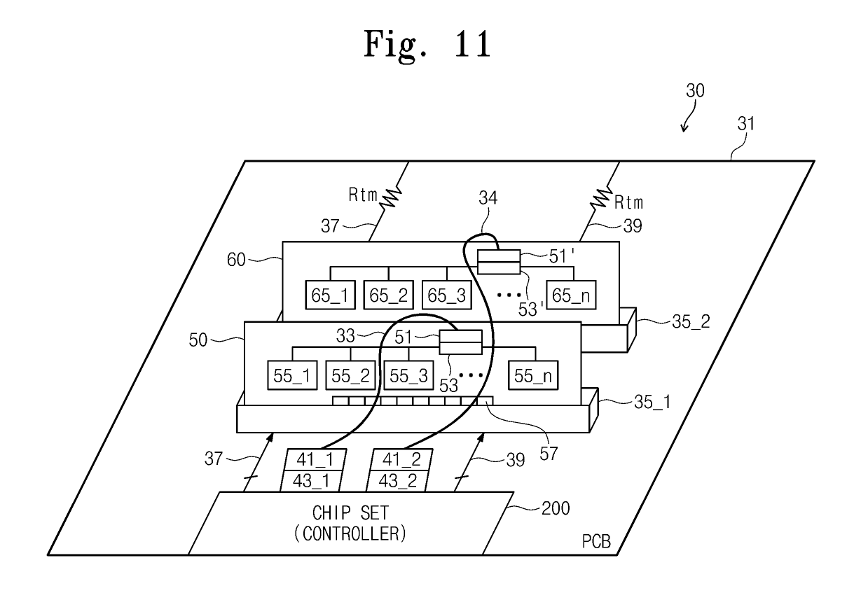

FIG. 11 is a block diagram schematically illustrating an exemplary memory system according to still another embodiment. Referring to FIG. 11, a memory system 30 with high-speed optical input/output may include a chipset 200 as a controller and memory modules 50 and 60 mounted on a PCB substrate 31. The memory modules 50 and 60 may be inserted in slots 35_1 and 35_2 installed on the PCB substrate 31. The memory module 50 may include a connector 57, DRAM memory chips 55_1 to 55_{—}n, an optical I/O input unit 51, and an optical I/O output unit 53.

The optical I/O input unit 51 may include a photoelectric conversion element (e.g., a photodiode) to convert an input optical signal into an electrical signal. The electrical signal output from the photoelectric conversion element may be received by the memory module 50. The optical I/O output unit 53 may include an electro-photic conversion element (e.g., a laser diode) to convert an electrical signal output from the memory module 50 into an optical signal. In some cases, the optical I/O output unit 53 may further include an optical modulator to modulate a signal output from a light source.

An optical cable 33 may perform a role of optical communications between the optical I/O input unit 51 of the memory module 50 and an optical transmission unit 41_1 of the chipset 200. The optical communications may have a bandwidth (e.g., more than score gigabits per second). The memory module 50 may receive signals or data from signal lines 37 and 39 of the chipset 200 through the connector 57, and may perform high-speed data communications with the chipset 200 through the optical cable 33. Meanwhile, resistors Rtm installed at lines 37 and 39 may be termination resistors.

In the memory system 30 with the optical I/O structure, a cache memory may be removed from the chipset 200. Instead, in the memory module 50, various cache memories may be embedded in the same chip.

The DRAM memory chips 55_1 to 55_{—}n may be used as a cache memory and a user data buffer in the memory system 30.

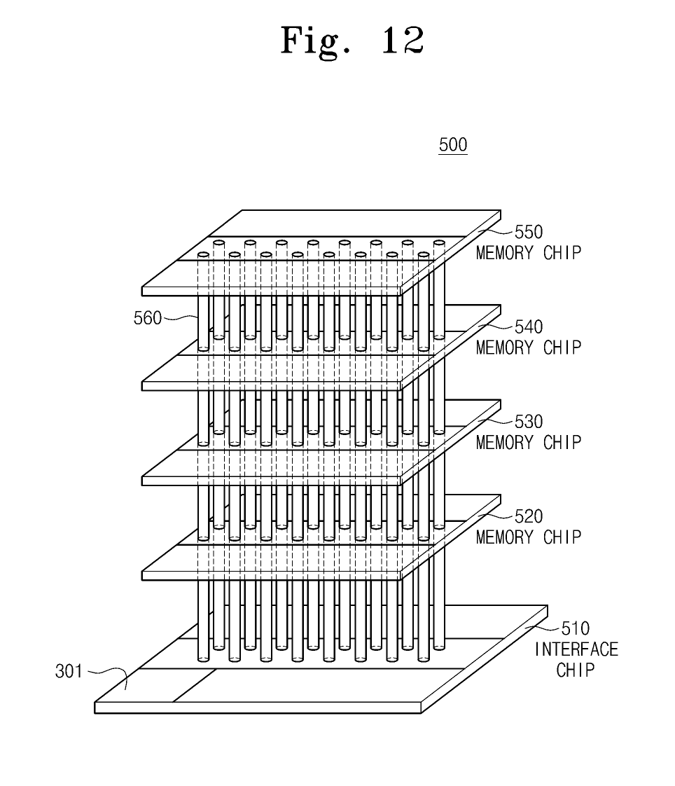

FIG. 12 is a diagram schematically illustrating an exemplary application of the disclosed embodiments, in which through-substrate via (TSV) is applied.

Referring to a stack type memory device 500 in FIG. 12, a plurality of memory chips 520, 530, 540, and 550 may be stacked on an interface chip 510 in a vertical direction. Herein, a plurality of TSVs, such as through-silicon vias 560 may be formed to penetrate the memory chips 520, 530, 540, and 550. Mass data may be stored at the three-dimensional stack package type memory device 500 including the memory chips 520, 530, 540, and 550 stacked on the interface chip 510 in a vertical direction. Also, the three-dimensional stack package type memory device 500 may be advantageous for high speed, low power and scale-down. A function block 301 formed at the interface chip 510 may be a management controller of FIG. 1.

In DRAMs of the memory chips 520, 530, 540, and 550 of the stack type memory device of FIG. 12, various cache memories may be embedded in the same chip.

Since a cache function of a chipset such as a memory controller or a CPU is replaced by a DRAM, a size of the chipset may be scaled down, and a fabricating yield may be bettered. Meanwhile, the DRAM may have a cache function, a merit of multi-chip packaging may be provided, and the product competitiveness may be bettered.

While the disclosure has been described with reference to exemplary embodiments, it will be apparent to those skilled in the art that various changes and modifications may be made without departing from the spirit and scope of the present disclosure. Therefore, it should be understood that the above embodiments are not limiting, but illustrative. For example, various changes and modifications on a manner of mounting a cache memory and a type of cache memory may be made without departing from the spirit and scope of the present invention.

What is claimed is:

1. A semiconductor memory device comprising:
a dynamic random access memory including a memory cell array formed of dynamic random access memory cells;
a cache memory formed at the same chip as the dynamic random access memory and configured to communicate with a processor or an external device ; and
a controller connected with the dynamic random access memory and the cache memory in the same chip and configured to control a dynamic random access function and a cache function.

2. The semiconductor memory device of claim 1, wherein the cache memory is configured to communicate with the processor or the external device without the need to communicate through circuitry of the dynamic random access memory.

3. The semiconductor memory device of claim 1, wherein the cache memory comprises a cache memory cell array having dynamic random access memory cells each having line loading smaller than the dynamic random access memory cells of the dynamic random access memory.

4. The semiconductor memory device of claim 1, wherein the cache memory comprises a cache memory cell array configured with the same layout as bit line sense amplifiers of the dynamic random access memory.

5. The semiconductor memory device of claim 1, wherein the cache memory comprises:
a first cache cell array configured with the same layout as bit line sense amplifiers of the dynamic random access memory; and
a second cache cell array formed of memory cells each having line loading smaller than the dynamic random access memory cells of the dynamic random access memory.

6. The semiconductor memory device of claim 1, wherein the cache memory is electrically connected to the processor through bumps.

7. The semiconductor memory device of claim 1, wherein the cache memory is electrically connected to the external device through bumps and through-substrate vias.

8. The semiconductor memory device of claim 1, wherein the semiconductor memory device and the processor are stacked on a printed circuit board and provided in the form of a package.

9. The semiconductor memory device of claim 1, wherein the cache memory comprises:
a first cache cell array configured with the same layout as bit line sense amplifiers of the dynamic random access memory; and
one of: an MRAM cache cell array formed of MRAM cells, an RRAM cache cell array formed of RRAM cells, or an SRAM cache cell array formed of SRAM cells.

10. A semiconductor memory device comprising:
a memory including a DRAM portion and a cache memory portion on the same chip;
the DRAM portion including circuitry sufficient to perform read and write operations on DRAM cells included in the DRAM portion in response to instructions from a controller; and
the cache memory portion including circuitry for performing caching functions in response to instructions from the controller, a processor, or an external device.

11. The semiconductor memory device of claim 10, wherein the cache memory portion comprises a cache memory cell array having DRAM cells each having line loading smaller than DRAM cells of the DRAM portion.

12. The semiconductor memory device of claim 10, wherein the cache memory portion is configured to perform faster read and write operations than the DRAM portion.

13. The semiconductor memory device of claim 10, wherein the cache memory portion is configured to communicate with a processor or an external device without the need to communicate through circuitry of the DRAM portion.

14. The semiconductor memory device of claim 10, wherein the cache memory portion is configured to communicate with a controller, processor, or external device through a first set of conductive terminals, and the DRAM portion is configured to communicate with a controller through a second set of conductive terminals that are separate from the first set of conductive terminals.

15. The semiconductor memory device of claim 10, wherein the semiconductor memory device is configured to communicate with a processor, and wherein semiconductor memory device and the processor are stacked on a printed circuit board and provided in the form of a package.

16. A semiconductor memory device comprising:
a dynamic random access memory (DRAM) portion including a first memory cell array formed of DRAM cells; and
a cache memory portion formed at the same chip as the DRAM portion and including a second memory cell array formed of DRAM cells;
wherein the cache memory portion is configured to perform faster read and write operations than the DRAM portion.

17. The semiconductor memory device of claim 16, further comprising:
a controller connected with the DRAM portion and the cache memory portion in the same chip and configured to control a dynamic random access function and a cache function.

18. The semiconductor memory device of claim 16, wherein the cache memory portion is configured to communicate with a processor or an external device without the need to communicate through circuitry of the DRAM portion.

19. The semiconductor memory device of claim 16, wherein the cache memory portion comprises a cache memory cell array having DRAM cells each having line loading smaller than the DRAM cells of the DRAM portion.

20. The semiconductor memory device of claim 16, wherein the cache memory portion is configured to communicate with a controller, processor, or external device through a first set of conductive terminals, and the DRAM portion is configured to communicate with a controller through a second set of conductive terminals that are separate from the first set of conductive terminals.
